(19) United States
(12) Patent Application Publication
(10) Pub. No.: US 2022/0099704 A1
(43) Pub. Date: Mar. 31, 2022

(54) CABLE HARNESS AND ASSET INDICATOR DEVICE FOR A DATA COMMUNICATION SENSING AND MONITORING SYSTEM

(71) Applicant: 3M INNOVATIVE PROPERTIES COMPANY, St. Paul, MN (US)

(72) Inventor: Shuguang Wu, Austin, TX (US)

(21) Appl. No.: 17/310,348

(22) PCT Filed: Feb. 25, 2020
(86) PCT No.: PCT/IB2020/051609

§ 371 Date: Jul. 28, 2021

Related U.S. Application Data
(60) Provisional application No. 62/813,994, filed on Mar. 5, 2019.

(51) Int. Cl. G01R 1/20; G01R 1/04; G01R 1/06; G01R 19/25; H04B 1/40; H04L 67/12; H01B 7/00

(52) U.S. Cl. CPC G01R 1/20; G01R 1/0416; G01R 1/06; H01B 7/0045; H04B 1/40; H04L 67/12; G01R 19/2513

(57) ABSTRACT

A sensor cable harness for coupling one or more sensors to at least one electrical asset of a power grid, comprises at least one sensor to sense a condition of the at least one electrical asset. At least one signal cable is configured to carry a sensor data signal from the at least one sensor to an electrical analytics unit (EAU). An asset indicator device is provided to at least temporarily couple to the at least one signal cable to indicate the at least one electrical asset being sensed by an assigned port of the EAU.

### BACKGROUND

Machine to machine communication is becoming increasingly important to the energy, communications, and security markets, among others. Supervisory Control and Data Acquisition (SCADA) systems used in those industries rely on inputs from remotely located sensors to function properly. SCADA systems can also output signals to actuate remote equipment in the field. A sizeable portion of that equipment (˜18% for U.S. electric utilities) is located underground and providing communications between above ground and underground equipment is a serious challenge.

With more proliferation of Distributed Energy Resources (DER), the power flow in the electric distribution grid no longer flow from primarily distribution sources (substations) to the primarily distribution loads all the time. At the same time, the awareness of abnormal power events (e.g. cable fault) and power quality (e.g. power factor, harmonics, voltage sag/swell) becomes more important as the utility companies seek better performance and customer satisfaction (SAIDI and SAIFI). There is increasing need for sensing and communicating power parameters at the distribution level.

Current methods used to locate underground cable faults are still slow and labor intensive. Even relatively short outages can be used against utilities and lead to rate adjustments for customers, so a faster means of locating and fixing underground faults is needed.

Thus, there is a need for communicating accurate data related to grid conditions related to electrical assets to/from a SCADA, such as into and out of underground equipment vaults and other structures where electrical assets are located.

### SUMMARY OF THE INVENTION

In one aspect of the invention, a sensor cable harness for coupling one or more sensors to at least one electrical asset of a power grid, comprises at least one sensor to sense a condition of the at least one electrical asset. At least one signal cable is configured to carry a sensor data signal from the at least one sensor to an electrical analytics unit (EAU). An asset indicator device is provided to at least temporarily couple to the at least one signal cable to indicate the at least one electrical asset being sensed by an assigned port of the EAU.

The above summary of the present invention is not intended to describe each illustrated embodiment or every implementation of the present invention. The figures and the detailed description that follows more particularly exemplify these embodiments.

### BRIEF DESCRIPTION OF THE DRAWINGS

The invention will be described hereinafter in part by reference to non-limiting examples thereof and with reference to the drawings, in which:

FIG. 1 is an isometric view of a cable harness and electrical analytic unit according to a first embodiment of the present invention.

FIG. 2 is an isometric view of a cable harness and electrical analytic unit (EAU) deployed as part of a data communication sensing and monitoring system according to another embodiment of the invention.

FIG. 3 is a schematic view of an exemplary implementation of several cable harnesses having asset indicator devices used to monitor multiple circuits of a switchgear, according to another embodiment of the invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION OF EMBODIMENTS

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “forward,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one aspect of the present invention, a sensor cable harness and an asset indicator device are used in conjunction with an electrical analytics unit (EAU) deployed as part of a data communication sensing and monitoring system to communicate information about at least one electrical asset, such as a power line, transformer, cable accessory, switch gear, or other electrical circuit from the asset location to a network, utility, or asset owner. In this manner, if the EAU has a limited set of input ports such that the number of input ports is less than that of the indexed asset positions, it may still be used to convey asset information about one or more electrical assets at the asset location, such as an underground manhole or handhole, or a pad mounted electrical asset location, as the asset indicator device sets and stores the asset position indexes and relays that information to the EAU. The asset indicator device can provide both a visual and electronic identification of the at least one electrical asset being sensed and/or monitored to a worker at the site and/or remotely to a network, utility, or asset owner.

The data communication sensing and monitoring system includes a robust wired and/or wireless transceiver that communicates between an asset location, such as a vault or underground enclosure, a cabinet, or an overhead asset location, and a utility, service, or monitoring network. In the case of wireless communication, the transceiver includes an antenna to provide radio transmission regarding accurate, real-time equipment conditions, with GPS electronics to provide positional and/or time synchronization information.

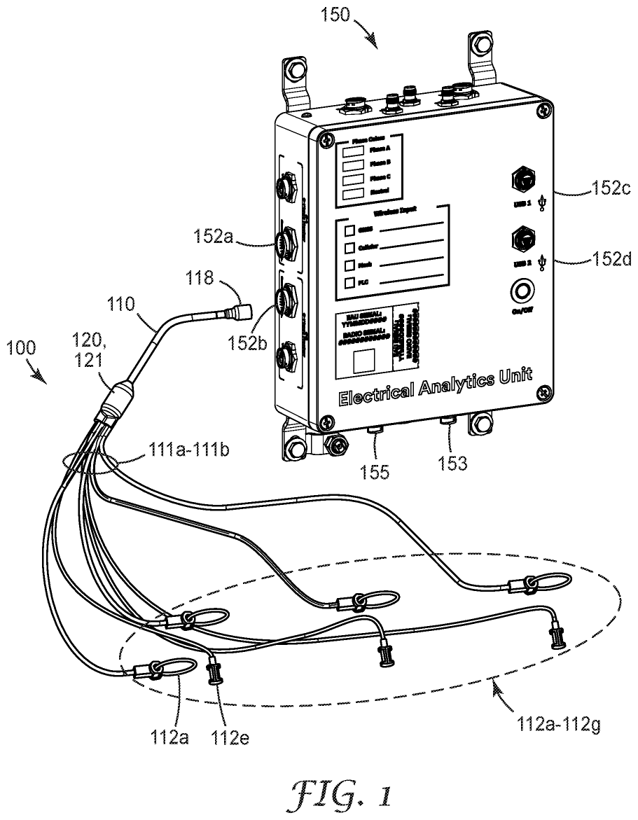

FIG. 1 shows an isometric view of a sensor cable harness 100 and electrical analytic unit (EAU) 150 according to a first embodiment of the present invention. Sensor cable harness 100 includes a signal cable 110 configured to carry sensor data signals from one or more individual sensor data signal lines (in this example, lines 111a-111g) which are coupled to one or more sensors (in this example, sensors 112a-112g). The signal cable 110 can comprise a conventional data signal cable. The signal cable 110 is configured to connect with a port of the EAU 150 via a cable connector 118, such as a conventional multipin connector.

The sensor cable harness 100 can also include a memory storage device 121 (e.g., an EPROM) coupleable to an asset indicator device 120.

The asset indicator device 120 can provide a visual and/or electronic indicator of the particular electrical asset being sensed by the sensors of cable harness 100 and communicates that identification information to a worker at the site and/or remotely to a network, utility, or asset owner. The asset indicator device allows a worker who is installing the sensor(s) on the electrical asset(s) to input a particular asset location (e.g., circuit #5) such that the indicator is visible to that worker (and any others at the site) and that position is electronically received by the EAU 150 when the cable harness 100 is plugged into the EAU 150. The asset indicator device can be a multi-numbered dial or LED device that tracks the user inputs and displays the number of the asset being sensed by that cable harness. Alternatively, the asset indicator device can be an electronic device that couples to the memory storage device and programs in a location number that is eventually read by the ESU (Electrical Sensing Unit) of the EAU 150 and communicated to the SCADA. As such, in one aspect, the asset indicator device 120 at least temporarily couples to the at least one signal cable to indicate the at least one electrical asset being sensed by an assigned port of the EAU 150 and provides that information to the memory storage device 121 incorporated in the sensor cable harness 100. In this regard, a single asset indicator device 120 can be used to provide asset identity information to multiple cable harnesses that are coupled to multiple electrical assets located at a site.

In another aspect of the invention, the asset indicator device 120 is integrated in (and is permanently part of) the sensor cable harness 100.

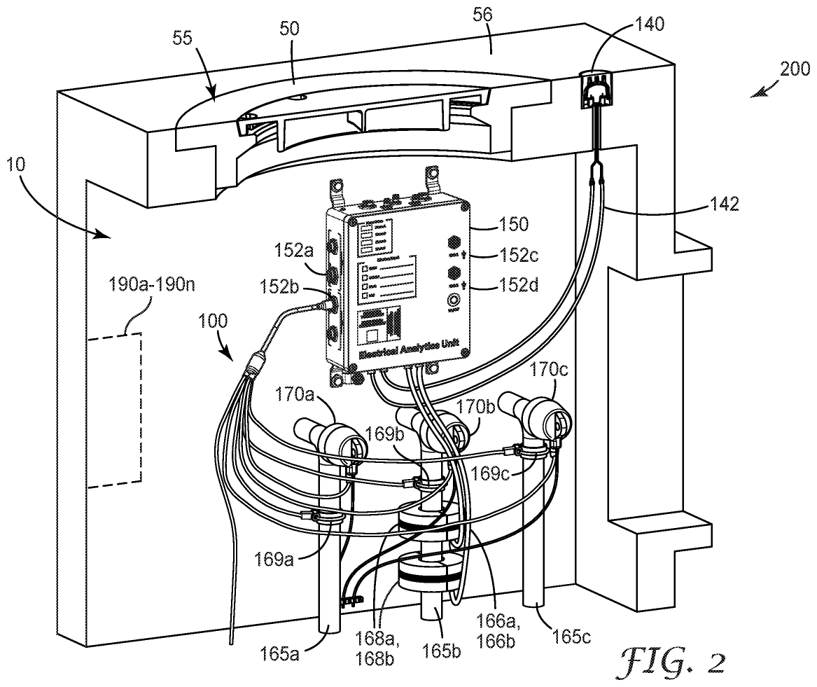

As mentioned above, the sensor cable harness 100 includes one or more sensors to sense a condition of at least one electrical asset at a particular site on a power grid. This site can include a vault, a manhole, a hand hole, a pad mounted (grade or above grade) cabinet, a substation, an overhead transmission line, or the like. In one aspect, as shown in FIG. 2, which is described in further detail below, the sensor cable harness can be employed to sense the condition of one or more electrical assets located in an underground vault.

In one example implementation, the power grid site can include one or more types of electrical assets or equipment, such as one or more high voltage electrical lines (such as electrical lines 165a-165c (carrying e.g., low, medium or high voltage power) such as shown in FIG. 2 described below), associated components and/or accessories (e.g., cable accessories), such as a splice or termination, a transformer, switchgear, further electrical lines to a nearby building or structure, a circuit, or any combination thereof.

The at least one sensor deployed at the electrical asset location or site includes at least one sensor or monitoring device disposed therein which can monitor a physical condition of the electrical asset or of the components, assets, or equipment located at the site. For underground locations or sites, such conditions would normally be difficult to gather or assess from above-ground. As described in detail below, in the embodiment shown in FIG. 2, an underground data communication system can provide a communication infrastructure to relay vault condition information to an above ground network or SCADA, without having a service technician physically enter the vault to determine those conditions.

As shown in FIG. 1, in this example, the sensors 112a-112g include multiple (in this case four) current sensors, such as sensor 112a, and multiple (in this case three) temperature sensors, such as sensor 112e. The current sensors can be implemented with Rogowski coils shown in more detail in FIG. 2 and the temperature sensors can be mounted onto or into the electrical equipment being monitored. Of course, other sensors can be provided that measure an electrical asset condition, such as voltage sensors, current sensors, temperature sensors, and or any combination thereof. Moreover, it is contemplated that the sensor cable harness can include or be used to deploy one or more of the following sensors or sensor types: power, voltage, current, temperature, combustible materials or byproducts of combustion, mechanical strain, mechanical movement (e.g. revolutions per minute), humidity, soil condition (acidity, moisture content, mineral content), pressure, hazardous atmosphere, liquid flow, leakage, component end-of-life or lifetime (e.g., a cathodic protection sensor), personnel presence (e.g., has someone entered the enclosure), physical state (e.g., is the enclosure open or closed, is the door open or closed, is a switch or valve open or closed, has an item been tampered with), light sensor, vibration (seismic, tampering). Thus, in this example, the sensors can provide real-time data about the condition of one or more connected power lines or of the site itself.

The sensor data signals, and asset indication signal, are carried by the cable harness to the electrical analytics unit (EAU) 150 disposed at the power grid site or location. EAU 150 is adapted to process data signals received from the sensors and transform such data signals into signals useable for an interested party (e.g., the utility that owns the power grid site or electrical asset owner) and/or in a supervisory control and data acquisition (SCADA) system. In addition, EAU 150 can also be adapted to receive signals from the SCADA system to control one or more components or equipment located at the asset site or location.

The EAU 150 can include a microcontroller or microprocessor unit, a power source, and electronics that can be built into or attached onto (via an interface connector panel) a site, such as a vault or enclosure, such as an IP68 rated enclosure or equipment cabinet. The EAU 150 can further include one or more ports or interfaces, such as sensor signal ports 152a-152d.

In one exemplary aspect, the EAU 150 can include two main functional units: a DCU (Digital Control Unit) and ESU (Electrical Sensing Unit) (each not shown, as they are integrated in EAU 150). In this example, the ESU has multiple (four are shown in the example of FIG. 1) ESMs (Electrical Sensing Modules), where each ESM can include a pair of sensing ports (e.g., current and voltage). In an example application, one voltage sensing port is used, and multiple current sensing ports can be used. In another aspect, the ESM(s) can be configured to receive current and voltage data signals in a single port.

In some aspects, the sensors can be remotely configurable via software updates received by the data communication sensing and monitoring system. In one aspect, sensor dongles can extend the sensor heads to various places in an underground environment.

The microcontroller or microprocessor include in the EAU 150 can comprise one or more chips or electronic devices that can provide operational control for the transceiver (see FIG. 2) and monitoring device or sensor(s).

One or both of the microcontroller or microprocessor and the monitoring device or sensors can comprise appropriate circuits and/or electronics to read sensor data, analyze the data, aggregate the data, classify the data, infer conditions based on the data, and take action based on the data. In addition, the EAU 150 can include a clock source (not shown) for event correlation.

The EAU 150 can further comprise interfaces or ports 153 and 155 for communicating with the transceiver and power harvesters (see FIG. 2, described below). Additional ports and interfaces can also be included in the EAU 150, depending on the application and asset location/environment.

In another aspect of the present invention, a data communication sensor and monitoring system 200 includes the above described EAU 150 and cable harness 100, as is shown in FIG. 2. In this example, the system 200 is an underground data communication system. The system 200 is disposed in an exemplary underground enclosure, here underground vault 10. In this example implementation, vault 10 includes a variety of equipment, such as one or more electrical lines, such as electrical lines 165a-165c (carrying e.g., low, medium or high voltage power), associated components and/or accessories, such as a splice or termination, a transformer, and further electrical lines to a nearby building or structure. In some vaults, a transformer may not be included therein.

The enclosure or vault 10 can be accessed from above ground via a portal or entrance port 55 that includes a conventional manhole cover 50, which can be formed from a metal and can have a conventional circular shape. In a one aspect, the manhole cover can be mounted on a ring, frame or flange structure of the entrance port 55 that is formed within a concrete pad or support structure 56 that covers and protects the vault or underground enclosure 10. In some instances, the support structure comprises a reinforced (with a rebar lattice) concrete pad, a thick metal plate, or a combination of a concrete pad with a metal cover plate surrounding the entrance port/manhole cover. In this aspect, vault 10 is can be constructed as a conventional underground vault, commonly used by electric, gas, water, and/or other utilities. However, in alternative aspects, system 200 can be utilized in another type of underground enclosure or similar structure, such as a manhole, basement, cellar, pit, shelter, pipe, or other underground enclosure.

The system 200 further includes a transceiver unit 140 securely mounted within the concrete pad or support structure 56. In this manner, communication from the vault to an outside network can be accomplished, as communicating radio signals through a metal manhole cover or a reinforced concrete pad, with supporting rebar disposed throughout, is extremely difficult and/or severely limited. A data communication system mountable to a vault entrance or manhole cover is described in PCT Pub. No. WO 2015/195861, incorporated by reference herein in its entirety.

As described above, the sensor cable harness 100 includes at least one sensor or monitoring device which can monitor a physical condition of the vault 10 or of the electrical asset(s) located in the vault. Such conditions would normally be difficult to gather or assess from above-ground. As described in detail below, the data communication system can provide a communication infrastructure to relay vault condition information to an above ground network or SCADA, without having a service technician physically enter the vault to determine those conditions.

As shown in FIG. 2, in this example, the sensors include voltage test points 170a-170c and Rogowski coils (current sensors) 169a-169c, that are deployed for a power cable, such as a low, medium or high voltage power cable 165a-165c. Other sensors can be provided that measure a cable condition, such as voltage, current, and/or temperature. Thus, in this example, the sensors can provide real-time data about the condition of one or more connected power lines.

For example, the Rogowski coils 169a-169c each produce a voltage that is proportional to the derivative of the current, meaning that an integrator can be utilized to revert back to a signal that is proportional to the current. Alternatively, a current sensor can be configured as a magnetic core current transformer that produces a current proportional to the current on the inner conductor. In addition, the voltage test points 170a-170c can each include a capacitive voltage sensor that provides precise secondary voltage measurements which are used to estimate the primary voltage. Because both a current sensor and a capacitive voltage sensor are provided in this example, these sensors facilitate calculation of phase angle (power factor) and power flow direction. Alternatively, a sensored termination can be deployed, such as is described in U.S. Pat. No. 9,742,180, incorporated by reference herein in its entirety.

As mentioned above, overall, it is contemplated that the electrical asset location or site can be monitored by sensors that include one or more of the following sensors: power, voltage, current, temperature, combustible materials or byproducts of combustion, mechanical strain, mechanical movement (e.g. revolutions per minute), humidity, soil condition (acidity, moisture content, mineral content), pressure, hazardous atmosphere, liquid flow, leakage, component end-of-life or lifetime (e.g., a cathodic protection sensor), personnel presence (e.g., has someone entered the enclosure), physical state (e.g., is the enclosure open or closed, is the door open or closed, is a switch or valve open or closed, has an item been tampered with), light sensor, vibration (seismic, tampering). For example, the system 200 can be implemented with a series of environmental sensors, such as gas (e.g., CH4, H2S, CO, etc.), water, and temperature (or humidity). Each sensor can have a hardware programmable unique I²C address. In addition, the sensors can each have one or more separate probes that extend into the environment (e.g., they can be sealed for continuous submersion in some applications).

In some aspects, the system 200 can interpret monitoring device/sensor information to determine environmental conditions such as the presence of hazardous gases, moisture, dust, chemical composition, corrosion, pest presence, and more. Further, the data communication system can send aggregated information such as periodic status or asynchronous alarm notifications upstream to another aggregation node or cloud server above ground. The data communication system can also respond to messages sent to it by an upstream aggregation node or cloud (e.g., SCADA) service. Typical commands from an upstream node or cloud service can include “transmit status,” perform action,” “set configuration parameter,” “load software,” etc.

As shown in FIG. 2, in this example, data from the sensors 112a-112g can be communicated via the sensor cable harness 100 to EAU 150. In this example, the EAU 150 can be mounted at a central location within the vault 10, or along a wall or other internal vault structure.

As mentioned above, EAU 150 is adapted to process data signals received from vault sensors and transform such data signals into signals useable for an interested party (e.g., the utility that owns the vault 10) and/or in a supervisory control and data acquisition (SCADA) system. In addition, EAU 150 can also be adapted to receive signals from the SCADA system to control one or more components or equipment located in the vault. As shown in FIG. 1, data can be communicated between EAU 150 and the transceiver unit 140 (described below) via cable 142, which can comprise one or more conventional coaxial and/or fiber cables. In an alternative embodiment, the EAU 150 can communicate with the transceiver unit 140 wirelessly and/or in combination with a wired connection.

The system 200 can further include an integrated sensor and/or a port or interface for connecting/attaching one or more (additional) sensors directly to the EAU 150. The module can be molded or machined to be made out of a thermoplastic or other type of molded materials. In some aspects, the sensors can be remotely configurable via software updates received by the data communication system. In one aspect, sensor dongles can extend the sensor heads to various places in an underground environment.

The microcontroller or microprocessor of the EAU 150 can comprise one or more chips or electronic devices that can provide operational control for the transceiver 140 and monitoring device or sensor(s) 112. In addition, the controller chips can be configured to require only low power levels, on the order of less than 10 W. The data communication system can integrate a very low power (e.g., <3 W), highly computational chipset with time synchronized events and configurable sensors. In addition, in one aspect, the integration of GPS capabilities along with time synchronous events leads to finding problem conditions with early detection with set thresholds and algorithms for a variety of incipient applications/faults/degradation of key structural or utility components.

One or both of the microcontroller or microprocessor in EAU 150 and the monitoring device or sensors coupled via sensor cable harness 100 can comprise appropriate circuits and/or electronics to read sensor data, analyze the data, aggregate the data, classify the data, infer conditions based on the data, and take action based on the data. In addition, the EAU can include a clock source (not shown) for event correlation.

In addition, system 200 can include one or more additional cable harnesses coupled to additional electrical assets 190a-190n, located at or near vault 10.

The system 200 further includes transceiver unit 140 that communicates information from (and to) the EAU 150 to (and from) the above ground SCADA or wireless communications network.

In another aspect, power can be provided to the components of the underground data communication system 200 through various means. In one aspect, equipment may be run via AC or DC power sources already located in the vault 10. If there is no available AC or DC power source, in another aspect, a power harvesting device 168a, 168b can be installed on electrical equipment, such as power lines 165a-165c that can provide power to the EAU 150 via cables 166a, 166b. Alternatively, piezoelectric transducers can be utilized to convert the mechanical vibration found within vault 10 to electrical energy that can be stored in batteries or super capacitors. For example, a conventional piezoelectric transducer is available from Mide (www.mide.com). In another aspect, thermoelectric transducers can be utilized to convert the natural temperature differential between above ground and below ground to electrical energy. For example, see (http://www.idtechex.com/research/reports/thermoelectric-energy-harvesting-2012-2022-devices-applications-opportunities-000317.asp).

An example communications flowchart illustrating an example communication scheme involving the sensor, the transceiver and a network, such as a mobile client application, is provided in U.S. Pat. No. 9,961,418, incorporated by reference in its entirety.

The transceiver unit 140 can include a housing having a main body portion and can include an antenna module and a GPS module to provide positional and or time synchronization information. Alternatively, the antenna module/GPS module may comprise a combination assembly, such as a MA131 Hercules antenna, that includes a GPS/GLONASS and 915 MHz ISM Band antenna (available from Taoglas Antenna Solutions). In this configuration, transceiver unit 140 is mounted in a hole or recessed portion 57 of concrete pad or support structure 56. In one alternative aspect, besides the GPS and antenna components, the transceiver unit 140 may further include processors, data storage units, communications interfaces, power supplies, and human interface devices.

The transceiver housing can be a sealed, robust structure and may include one or more housing parts such as a cover and base plate. At least some of the housing parts may be made of a moldable plastic material. The transceiver unit/housing can be molded from a thermoplastic, machined, extruded, or it can be constructed from a conventional manufacturing process. The material of the housing parts may be resistant against aggressive substances. The housing can be sealed to protect the antenna and GPS components contained within it. By using a seal of appropriate material, such as a graphite-containing material, a seal may additionally be provided against aggressive substances like gasoline or oil which may be present in an outside environment.

The transceiver 140 can be mounted using a conventional potting material and/or adhesive, such as those used in pavement marking applications, to secure the transceiver position within the concrete pad 56. In addition, a channel 58 can be provided in the concrete pad 56 to allow for passage of the one or more data signal cables 142 to pass from the transceiver 140 to the vault equipment, such as EAU 150.

The antenna(s), electric or electronic components contained within the transceiver housing can be active, passive, or both active and passive. Thus, the transceiver housing makes it possible to mount an antenna on the outside surface of an underground vault or enclosure while allowing the antenna to be electrically connected to, e.g., EAU 150, located in the vault.

In another aspect, multiple antennas can be embedded in transceiver 140 allowing for multiple communication methods both above and below ground. For example, WiFi and 4G antennas can be embedded in the transceiver housing 141 along with a GPS antenna to provide multiple network connections along with GPS positioning and timing information. A Bluetooth antenna can be embedded in the transceiver 140 to provide local communications to personnel in close proximity to the transceiver unit. For example, a craft person driving over a transceiver/gateway unit could directly read the sensors in the vault below using Bluetooth. An RFID antenna can be embedded in the transceiver to permit reading underground sensor data with an RFID reader. Overall, in alternative aspects, communication methods such as WiFi, WiMax, mobile telephone (3G, 4G, LTE, 5G), private licensed bands, etc., can be utilized.

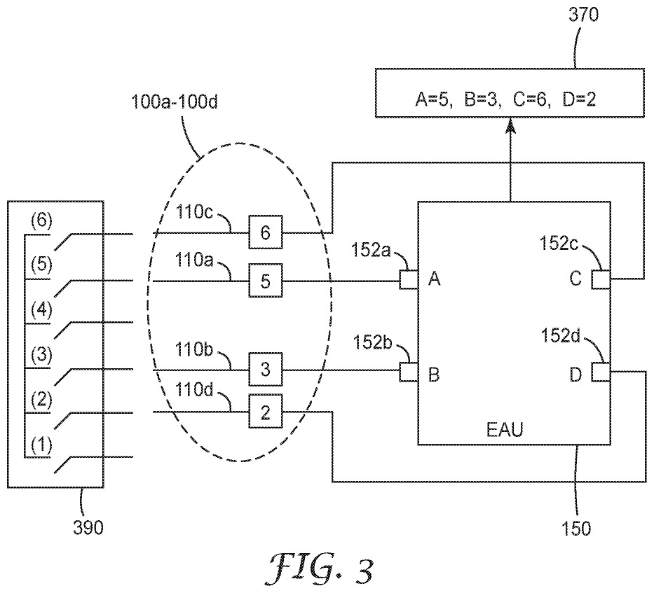

As mentioned previously, the asset indicator device 120 can provide a visual and/or electronic indicator of the particular electrical asset being sensed by the sensors of cable harness 100 and communicates that identification information to a worker at the site and/or remotely to a network, utility, or asset owner. The asset indicator device allows a worker who is installing the sensor(s) on the electrical asset(s) to input a particular asset location (e.g., circuit 5) such that the indicator is visible to that worker (and any others at the site) and that position is electronically received by the EAU 150 when the cable harness 100 is plugged into the EAU 150. An example implementation of multiple sensor cable harnesses being deployed at a multi-circuit switch site (e.g., a switchgear 390) is shown schematically in FIG. 3.

In this example, the switchgear 390 has six circuits that can be monitored, while the EAU has only four input ports (152a-152d, also denoted as A, B, C, D). By using the asset indicator device in each cable harness 100a-100d/signal cable 110a-110d, a worker can install the cable harnesses on particular assets (here switches 2, 3, 5 and 6) that are required to be monitored for a particular application (e.g., Fault Circuit Indicator, or FCI). Thus, sensor cable harness 100a/signal cable 110a is monitoring switch position 5, sensor cable harness 100b/signal cable 110b is monitoring switch position 3, sensor cable harness 100c/signal cable 110c is monitoring switch position 6, and sensor cable harness 100d/signal cable 110d is monitoring switch position 2. When the cable harnesses 100a-100d are plugged into the input ports on EAU 150, the ESU (Electrical Sensing Unit) reads and stores the circuit positions and relays that to the DCU (Digital Control Unit) of the EAU 150. The DCU maps the positions and ports (A=5, B=3, C=6, D=2) for monitoring and reporting to SCADA/network 370. In this example, the asset indicator devices include LED displays, proving the asset mapping to the worker.

Thus, with this construction, if a sensor, senses a line or circuit fault, transceiver unit 140 can communicate real-time fault location information to a power utility network or SCADA system.

What is claimed is:

1. A sensor cable harness for coupling one or more sensors to at least one electrical asset of a power grid, comprising:
at least one sensor to sense a condition of the at least one electrical asset;
at least one signal cable configured to carry a sensor data signal from the at least one sensor to an electrical analytics unit (EAU);
an asset indicator device at least temporarily coupled to the at least one signal cable to indicate the at least one electrical asset being sensed by an assigned port of the EAU.

2. The sensor cable harness of claim 1, further comprising a memory storage device.

3. The sensor cable harness of claim 2, wherein the asset indicator device is integrated in the sensor cable harness.

4. The sensor cable harness of claim 2, wherein the asset indicator device is a removable device that communicates an asset position to the memory storage device.

5. The sensor cable harness of claim 1, comprising multiple sensors for sensing the condition of multiple electrical assets or multiple portions of a single electrical asset.

6. The sensor cable harness of claim 1, wherein the at least one electrical asset is located underground.

7. The sensor cable harness of claim 1, wherein the EAU is located underground.

8. The sensor cable harness of claim 1, wherein the electrical asset comprises one of a power line, a cable accessory, a transformer, a switch gear, and a circuit.

9. The sensor cable harness of claim 1, wherein said at least one sensor is selected from the group consisting of current sensors, voltage sensors, and temperature sensors.

10. The sensor cable harness of claim 1, wherein the asset indicator device comprises a programmable position indicator.

11. The sensor cable harness of claim 1, wherein the asset indicator device comprises an electrical and a visual indication of the at least one electrical asset coupled to the cable harness.

12. A data communication sensor and monitoring system, comprising:
an electrical analytics unit (EAU) having one or more data signal entry ports;
a sensor cable harness for coupling at least one sensor to the at least one electrical asset of a power grid to sense a condition of the at least one electrical asset, wherein the sensor cable harness includes at least one signal cable configured to carry a sensor data signal from the at least one sensor to the EAU;
an asset indicator device at least temporarily coupled to the at least one signal cable to indicate the at least one electrical asset being sensed by an assigned port of the EAU; and
a transceiver including an antenna and global positioning system (GPS) circuitry configured to communicate with a network, wherein the EAU processes the data from the at least one sensor, generates a processed data signal, and communicates the processed data signal to the transceiver, wherein the processed data signal includes an identity of the electrical asset being monitored by the at least one sensor.

13. The data communication sensor and monitoring system of claim 12, wherein the at least one electrical asset is located underground.

14. The data communication sensor and monitoring system of claim 12, wherein the EAU is located underground.

15. The data communication sensor and monitoring system of claim 12, wherein the at least one sensor detects at least one of: temperature, combustible materials or byproducts of combustion, mechanical strain, mechanical movement, humidity, soil condition, pressure, hazardous atmosphere, liquid flow, leakage, component end-of-life or lifetime, personnel presence, physical state, light level, and vibration.

16. A method for providing a central office of a utility with the identity of an electrical asset being sensed at a sensing location, comprising:
providing an electrical analytics unit (EAU) having one or more data signal entry ports at the sensing location;
providing a sensor cable harness for coupling one or more sensors to at least one electrical asset of a power grid, wherein the sensor cable harness includes at least one signal cable configured to carry a sensor data signal from the at least one sensor to the EAU;
providing an asset indicator device at least temporarily coupleable to the at least one signal cable;
assigning an identity of the at least one electrical asset to a memory storage device disposed in the sensor cable harness;
connecting the sensor cable harness to a corresponding port in the EAU;
indicating the at least one electrical asset being sensed by the corresponding port of the EAU;
sensing a condition of the at least one electrical asset;
processing the data from the at least one sensor and generating a processed data signal; and
communicating the processed data signal to the central office of the utility, wherein the processed data signal includes a correspondence of the at least one electrical asset to the connected corresponding EAU port.
